(19) United States
(12) Patent Application Publication
(10) Pub. No.: US 2015/0008566 A1
(43) Pub. Date: Jan. 8, 2015

(54) METHOD AND STRUCTURE OF PANELIZED PACKAGING OF SEMICONDUCTOR DEVICES

(71) Applicant: Texas Instruments Incorporated, Dallas, TX (US)

(72) Inventors: Mark A. Gerber, Lucas, TX (US); Mutsumi Masumoto, Beppu Oita (JP); Kenji Masumoto, Hiji Hayami Gun (JP); Anindya Poddar, Sunnyvale, CA (US); Kengo Aoya, Beppu Oita (JP); Masamitsu Matsuura, Beppu Oita (JP); Takeshi Onogami, Beppu Oita (JP)

(21) Appl. No.: 14/320,803

(22) Filed: Jul. 1, 2014

Related U.S. Application Data
(60) Provisional application No. 61/842,151, filed on Jul. 2, 2013.

(51) Int. Cl. H01L 23/00; H01L 23/495

(52) U.S. Cl. CPC H01L 24/97; H01L 23/49575
USPC 257/668; 438/107

(57) ABSTRACT

A method for fabricating packaged semiconductor devices in panel format; placing a panel-sized metallic grid with openings on an adhesive tape (292); attaching semiconductor chips—coated with a polymer layer having windows for chip terminals —face-down onto the tape (293); laminating low CTE insulating material to fill gaps between chips and grid (294); turning over assembly to place carrier under backside of chips and lamination and to remove tape (295); plasma-cleaning assembly front side, sputtering uniform metal layer across assembly (296); optionally plating metal layer (297); and patterning sputtered layer to form rerouting traces and extended contact pads for assembly (298).

### CROSS-REFERENCE TO RELATED APPLICATIONS

This application claims priority to U.S. Provisional Application No. 61/842,151 filed on Jul. 2, 2013. Said application incorporated herein by reference for all purposes.

### FIELD

Embodiments of the invention are related in general to the field of semiconductor devices and processes, and more specifically to the structure and fabrication method of panelized packaging for embedded semiconductore devices.

### DESCRIPTION OF RELATED ART

It is common practice to manufacture the active and passive components of semiconductor devices into round wafers sliced from elongated cylinder-shaped single crystals of semiconductor elements or compounds. The diameter of these solid state wafers may reach up to 12 inches. Individual devices are then typically singulated from the round wafers by sawing streets in x- and y-directions through the wafer in order to create rectangularly shaped discrete pieces from the wafers; commonly, these pieces are referred to as die or chips. Each chip includes at least one device coupled with respective metallic contact pads. Semiconductor devices include many large families of electronic components; examples are active devices such as diodes and transistors like field-effect transistors, passive devices such as resistors and capacitors, and integrated circuits with sometimes far more than a million active and passive components.

After singulation, one or more chips are attached to a discrete supporting substrate such as a metal leadframe or a rigid multi-level substrate laminated from a plurality of metallic and insulating layers. The conductive traces of the leadframes and substrates are then connected to the chip contact pads, typically using bonding wires or metal bumps such as solder balls. For reasons of protection against environmental and handling hazards, the assembled chips may be encapsulated in discrete robust packages, which frequently employ hardened polymeric compounds and are formed by techniques such as transfer molding. The assembly and packaging processes are usually performed either on an individual basis or in small groupings such as a strip of leadframe or a loading of a mold press.

In order to increase productivity by a quantum jump and reduce fabrication cost, technical efforts have recently been initiated to re-think certain assembly and packaging processes with the goal to increase the volume handled by each batch process step. These efforts are generally summarized under the title panelization. As an example, adaptive patterning methods have been described for fabricating panel-based package structures. Other technical efforts are directed to keep emerging problems such as panel warpage under control.

### SUMMARY OF THE INVENTION

Applicants realized that successful methods and process flows for large-scale panels in the range from 16″×20″ to 21″×25″, as intended for semiconductor packaging, have to resolve key technical challenges. Among these challenges are achieving planarity of panels and avoiding warpage and mechanical instability, achieving low resistance connections and reaching high reliability backside chip connects, avoiding expensive laser process steps, especially through metal layers and epoxy layers, and improved thermal characteristics. For metallic seed layers, uniformity of the layers across the selected panel size should be achieved, yet electroless plating technology should be avoided. Further, the metallic seed layers nedd to strongly adhere to a variety of materials including silicon, metals, and insulators.

Applicants solved the challenges when they discovered process flows for packaged semiconductor devices which use adhesive tapes instead of epoxy chip attach procedures; and a sputtering methodology for replacing electroless plating; furthermore, the new process technology is free of the need to use lasers. As a result, the new process flows preserve clean chip contact pads and offer the opportunity to process both sides of a panel concurrently, greatly increasing productivity. In addition, the packaged devices offer improved reliability. A key contributor to the enhanced reliability is reduced thermo-mechanical stress achieved by laminating gaps with insulating fillers having high modulus and a glass transition temperature for a coefficient of thermal expansion approaching the coefficient of silicon.

Applicants adopted and modified a sputtering technology with plasma-cleaned an cooled panels, which produces uniform sputtered metal layers across a panel and thus avoids the need for electroless plating. Since the plasma-cleaning and sputtering procedure also serves to clean and roughen the substrate surface, the sputtered layers adhere equally well to dielectrics, silicon, and metals; they may be employed as connective traces, or may serve as seed layers for subsequent electro-plated metal layers.

Certain flows based on the modified processes may be applied to a plurality of discrete chips individually assembled on large panels; it is a technical advantage that other flows lend themselves to a plurality of whole semiconductor wafers before chip singulation. Many modified flows are applicable to any transistor or integrated circuit; other modified flows are particularly suitable forspecifically MOS field effect transistors (FETs), which have terminals on both chip sides. It is another technical advantage that some of the packaged devices offer flexibility with regard to the connection to external parts: they can be finished to be suitable as devices with land grid arrays, or as ball grid arrays, or as and QFN (Quad Flat No-Lead) terminals. Another family of packaged devices based on an inventive process flow offers dual purpose layer-to-layer interconnects that are also used as locating fiducials in the assembly process and may be operational on the front as well as on the back side of the packages.

### BRIEF DESCRIPTION OF THE DRAWINGS

FIG. 1A shows a perspective view of a packaged semiconductor device according to the invention, wherein the device may be employed as a land grid array, a ball grid array, or a QFN (Quad Flat No-Lead) device.

FIG. 1B illustraters a cross section of another packaged semiconductor device according to the invention, wherein the device may be employed as a land grid array, a ball grid array, or a QFN (Quad Flat No-Lead) device.

FIGS. 2A, 2B, and 2C show a process flow for fabricating semiconductor packages in panel format.

FIG. 3 depicts another process flow for fabricating semiconductor packages in panel format.

FIGS. 4A and 4B illustrate another process flow for fabricating semiconductor packages in panel format.

FIG. 5 shows another process flow for fabricating semiconductor packages in panel format.

FIGS. 6A and 6B depict another process flow for fabricating semiconductor packages in panel format.

FIGS. 7A and 7B illustrate another process flow for fabricating semiconductor packages in panel format.

FIGS. 8A, 8B, and 8C show another process flow for fabricating semiconductor packages in panel format.

### DETAILED DESCRIPTION OF THE PREFERRED EMBODIMENTS

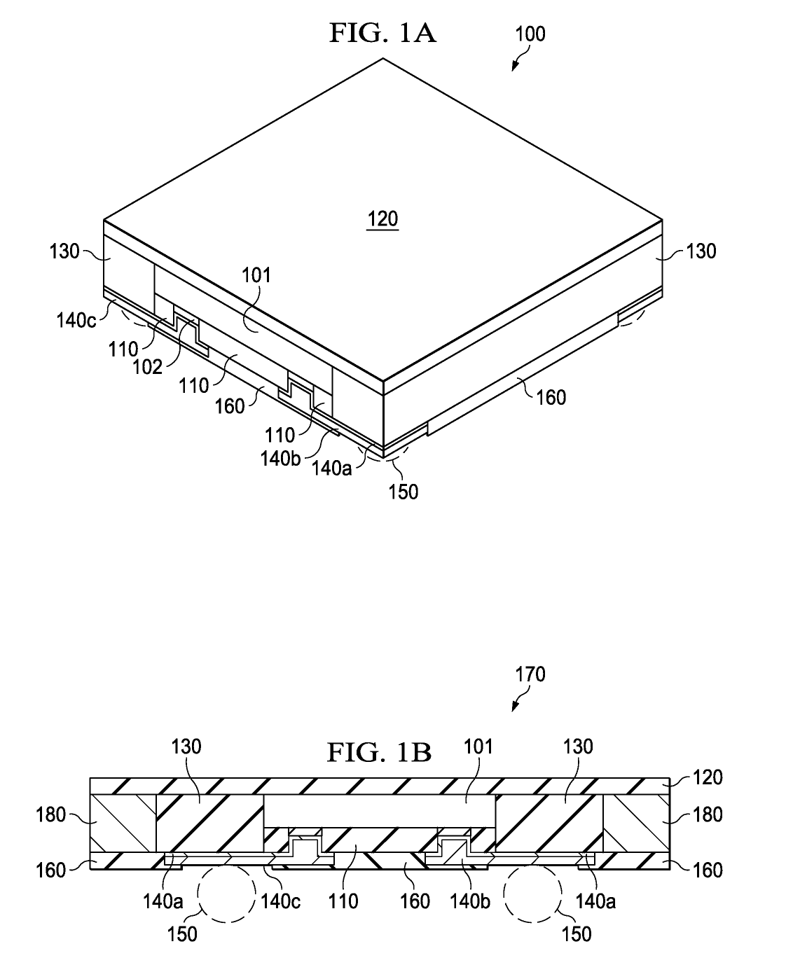

FIG. 1A illustrates an exemplary embodiment, a semiconductor device generally designated 100 having a semiconductor chip 101 encapsulated in a package, which has been fabricated in a process flow suitable for executing the sequence of process steps in panel form. The panel refers to a substrate having a composition to embed semiconductor chips within the emerging package to produce an integrated device, and further having a size larger than 16″ lateral dimension to execute the process steps as batch processes, thus allowing drastic fabrication cost reduction. Panels may be square or rectangular, and reach sizes of 20″ by 20″ to 28″ by 28″, or larger, and may be suitable for attaching a plurality of semiconductor whole wafers (for example four wafers of 12″ diameter), or a plurality of semiconductor chips.

In FIG. 1A, chip 101 may include an integrated circuit (IC) with terminals 102. The terminals are metallized; as examples, they may be aluminum pads or copper bumps. The active surface of chip 101 is protected by a layer 110 of an inert polymeric material such as polyimide, which has been applied to the surface of the semiconductor wafer before wafer singulation. Layer 110 has a plurality of openings to expose the terminals 102. The passive back side of chip 101 is attached to sheet 120, which is based on glass fibers impregnated with a gluey resin selected for a coefficient of thermal expansion (CTE) close to the CTE of silicon. Sheet 120 is often referred to as pre-preg film.

At the sidewalls of chip 101 in device 100 in FIG. 1A are dielectric regions 130, which have been created in a lamination process using a compliant insulating polymeric filler material under vacuum suction. Resting on regions 130 are conductive re-distributing layers 140a and 140b. Layer 140a comprises at least one metal seed layer created by a sputtering process (see below), and (optional) layer 140b comprises at least one plated metal layer. Both layers 140a and 140b contact chip terminals 102 and form conductive traces from terminals 102 to the enlarged terminals 140c of the device package. Terminals 140c of device 100 may be structured as land grid arrays, or as ball grid arrays as indicated by solder balls 150 in FIG. 1A, or as QFN-type (Quad Flat No-Lead) package terminals.

It is preferred that the majority of the package surface, which does not serve as terminal areas, is protected by a rigid layer 160; a preferred choice is an insulator commonly called solder mask.

FIG. 1B shows a device 170, which is a modification of device 100. In addition to the same parts as device 100, device 170 includes metallic regions 180, which are covered by pre-preg film 120 and solder mask 160, respectively. Regions 180 originate from a window frame conveniently used in the fabrication process (see below). Regions 180 add to the rigidity and stability of device 170, but do not contribute to package terminals 140c, since regions 180 are covered with insulating solder mask 160.

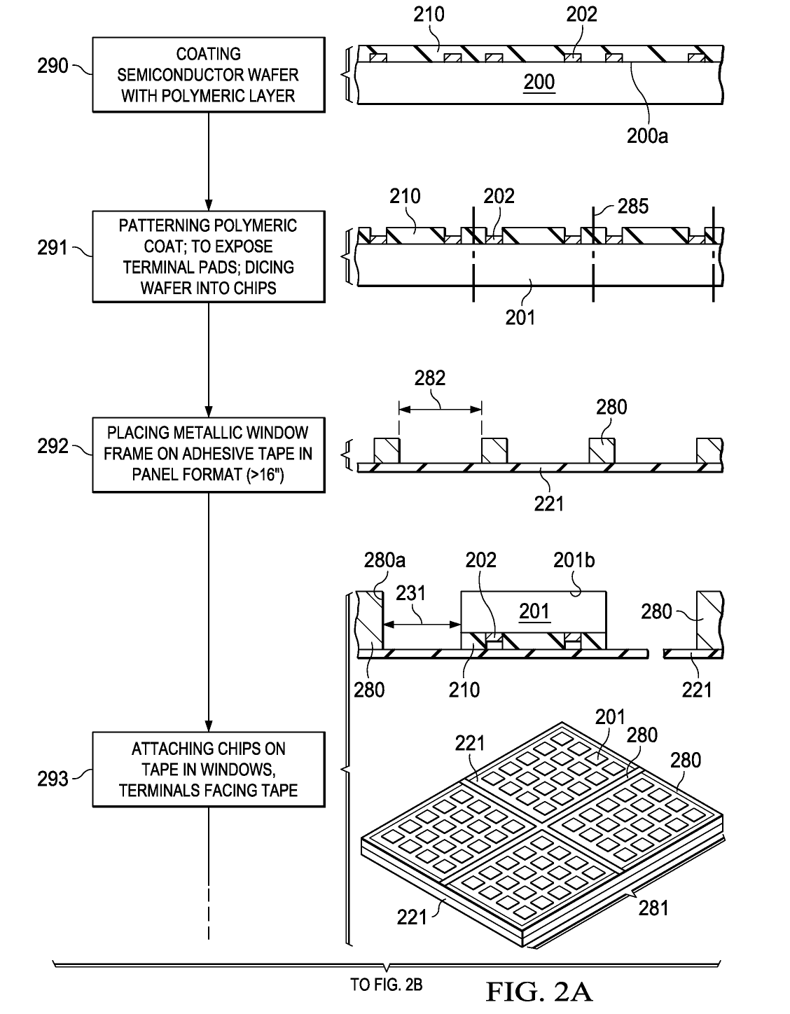

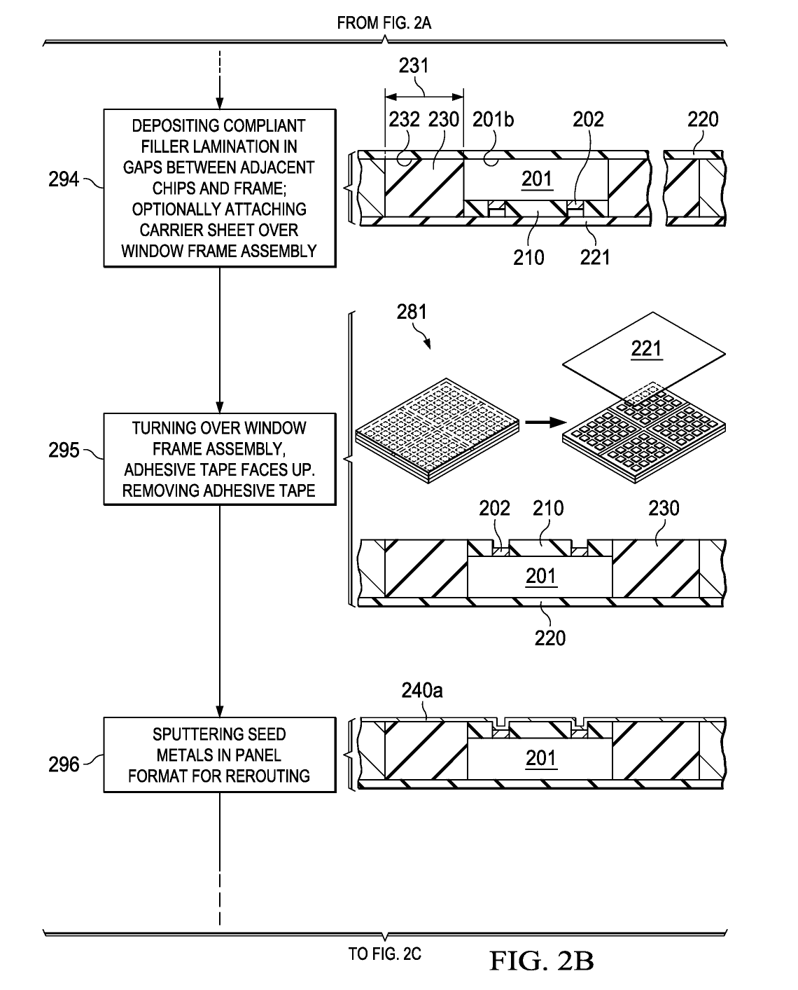

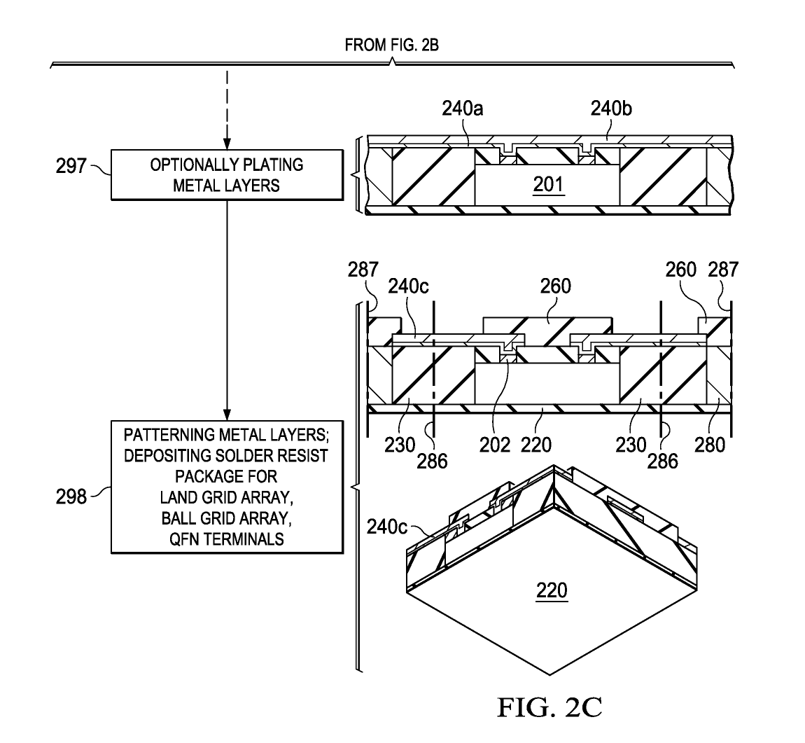

Another embodiment is a method for fabricating packaged semiconductor devices in panel format, shown in exemplary FIGS. 2A, 2B, and 2C. The figures illustrate certain steps of the panel format fabrication flow to manufacture devices 100 and 170. FIG. 2A shows a semiconductor wafer 200 with a plurality of devices along surface 200a; the devices may be transistors or integrated circuits, or other active devices. On surface 200a, each device has a plurality of metallized terminal pads 202, which may be aluminum pads or metal bumps. (In other semiconductor wafers, devices may have at least one terminal on the surface opposite 200a.) The process flow starts with step 290: The wafer surface 200a with its plurality of active devices and terminals is coated with a layer 210 of insulating inert polymeric material, such as polyimide.

In the next process step 291, the polymeric coat 210 is patterned in order to expose the terminal pads 202 of the devices. Thereafter, wafer 200 is diced along lines 285 into discrete chips 201. As shown in FIG. 2A, each chip 201 has a surface 201a with the active device and terminal pads 202, and a passive back surface 201b. Alternatively, the back surface of other devices may include at least one terminal.

In process step 292, an adhesive tape 221 is provided; preferably tape 221 is silicone-based. Then, a large metallic window frame 281 with a plurality of metal rims 280 is attached to the tacky surface of tape 221; a preferred metal of the frame is copper. Frame 281 defines the panel size; in this case, a large size of panel implies, for example, a format of 16″ by 20″, or larger; a panel of this size provides to the panel-format process flow a throughput volume 3.5 times the volume of an 8″ wafer. A batch process of this magnitude can improve productivity substantially. The frame includes a plurality of openings, or windows, framed by metallic rims 280 with sidewalls. The size 282 of an individual window is such that at least one chip 201 fits into the window, preferably a plurality of chips 201 aligned in an orderly array or grid. In the array, chips 201 are spaced from frame sidewalls 280a by gaps 231; similarly, adjacent chips are spaced by gaps from each other. The warpage of panel 281 is kept under control and minimized by the subsequent process steps and materials (see below).

In process step 293, semiconductor chips 201 are attached to tape 221 inside the windows of frame 281. Chips 201 are oriented so that chip terminals 202 face tape 221 and polymeric layer 210 is attached to tape 221. In this position, chip terminals 202 are protected from external influences and can thus conserve their original cleanliness. The perspective view of step 293 in FIG. 2A shows panel 281 after all windows surrounded by rims 280 have been populated with chips 201, arranged in an orderly array while spaced and attached to tape 221 with the chip terminals facing tape 221. The process flow continues in FIG. 2B.

The process of step 294 in FIG. 2B summarizes several steps. The gaps 231 between chips and frame sidewalls and between adjacent chips are cohesively filled by a process, in which, under vacuum suction, a compliant insulating material 230 is laminated, thereby forming an assembly with a planar surface 232 with the back surface 201b of the chips. The compliant material is selected so that it exhibits a high modulus and low coefficient of thermal expansion (CTE) approaching the CTE of the semiconductor chips. It is an option to use a leveling or grinding technique to achieve proper planarity.

Next, a carrier sheet 220 is placed over the assembly and attached to the planar surface 232 and 201b. The sheet, which is often referred to as a pre-preg film, is based on composite material including glass fiber impregnated with a gluey resin and selected for a CTE close to the CTE of silicon. Alternatively, for some device types the attachment of the carrier sheet is omitted.

In the next process step illustrated in step 295, panel 281 is turned over so that adhesive tape 221 faces up. Then, the adhesive tape 221 is removed, if necessary by raising the temperature. This action exposes the clean metallized terminal pads 202 of the chips surrounded by polymeric coat 210. Thereafter, panel 281 with its assembly is transferred to the vacuum and plasma chamber of an apparatus for sputtering metals.

During the processes summarized in step 296, the assembly of panel 281, with the exposed terminal pads, chip coats, and lamination surfaces, is plasma-cleaned. The plasma accomplishes, besides cleaning the surface from adsorbed films, especially water monolayers, some roughening of the surfaces; both effects enhance the adhesion of the sputtered metal layer. While the panel is being cooled, at least one layer 240a of metal is sputtered, at uniform energy and rate, onto the exposed chip and lamination surfaces across the panel. The sputtered layer adheres to the multiple surfaces by energized atoms that penetrate the top surface of the panel, creating a non-homogeneous layer between the surface material and sputtered layers.

Preferably, the step of sputtering includes the sputtering of a first layer of a metal selected from a group including titanium, tungsten, tantalum, zirconium, chromium, molybdenum, and alloys thereof, wherein the first layer is adhering to chip and lamination surfaces; and without delay sputtering at least one second layer of a metal selected from a group including copper, silver, gold, and alloys thereof, onto the first layer, wherein the second layer is adhering to the first layer. The sputtered layers have the uniformity, strong adhesion, and low resistivity needed to serve, after patterning, as conductive traces for rerouting; the sputtered layers may also serve as seed metal for plated thicker metal layers.

In optional step 297, at least one layer 240b of metal is electroplated onto the sputtered layers 240a. A preferred metal is copper. The plated layer is preferably thicker than the sputtered metal to lower the sheet resistance and thus the resistivity of the rerouting traces after patterning the plated and sputtered metal layers. Next, step 298 in FIG. 2B illustrates the processes of patterning the sputtered and plated metal layers in order to create connecting traces between chip terminal pads 202 and enlarged contact pads 240c, which are positioned over the laminated material 230. It is preferred to execute the step of patterning with a laser direct-imaging technology. The laser direct-imaging technology uses an out-alignment correcting technique.

In addition, it is preferred to deposit and pattern rigid insulating material 260, such as so-called solder resist, to protect and strengthen remaining chip areas not used for extended contacts and between the rerouting traces. In order to apply to a large panel solder resist and other dielectric materials, photo-imagable materials, etchants, and others, a preferred recent technique uses an ultrasonic spray tool.

In the next process step, panel 281 is singulated into discrete devices; the preferred separating technique is sawing. The cuts may be made through laminated material 230 along lines 286 in FIG. 2B, or they may be made through metal rims 280 of suitable frames along lines 287 in FIG. 2B. The perspective view of a discrete device shown for step 298 in FIG. 2B illustrates a singulated devices sawed by the former cutting option so that some of the enlarged contact pads 240c are positioned at the corners of the discrete device. As mentioned above, devices like the one shown and related devices can be utilized as land grid array devices, ball grid devices, and QFN (Quad Flat No-Lead) type devices.

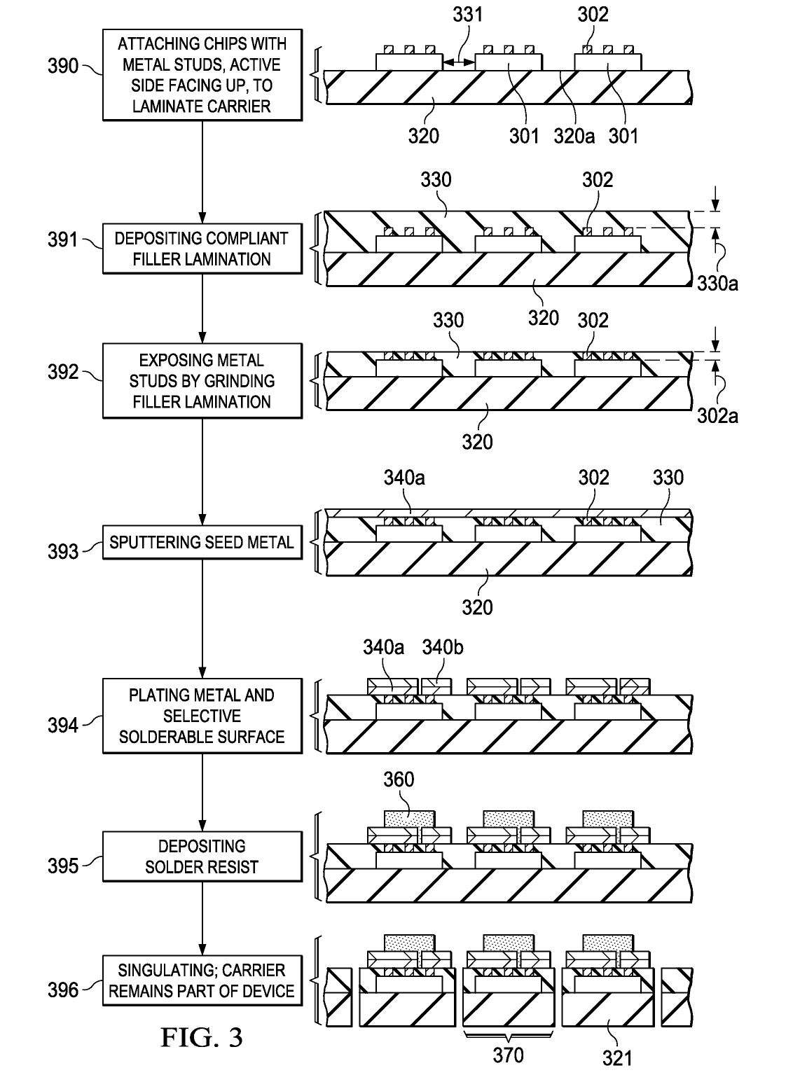

Another embodiment is an exemplary method for fabricating packaged semiconductor devices in panel format, illustrated in FIG. 3. The method starts by selecting a laminate rigid carrier 320 with a dielectric and tacky-coated surface 320a (adhesive may also be spray-coated or laminated). The carrier has panel size, i.e., lateral dimensions larger than at least one semiconductor wafer, and is thus suitable for the attachment of a large number of semiconductor chips. The composition of carrier 320 is such that its material can become a permanent part of the final packaged devices. Furthermore, semiconductor chips 301 are provided, where the terminal pads of the devices on a chip surface have metal bumps 302. The chips may have a thickness of about 150 μm, and preferred bumps include round or square copper pillars, and squashed copper (or gold or silver) balls (as formed by wire bonding).

In process step 390 of FIG. 3, a plurality of semiconductor chips 301 is attached onto the dielectric surface 320a of panel sheet 320 as a carrier. The chips are oriented so that the metal bumps 302 of the chip terminal pads face away from the panel surface. Preferably, a plurality of chips is aligned in an orderly array or grid, wherein chips 301 are spaced from each other by gaps 331.

In step 391, a compliant insulating material 330 is laminated, under vacuum suction, in order to cohesively fill any gaps 331 between the chips and to cover the chip surfaces and bumps 302. Preferably, the height 330a of the laminated material over the bump tops is between about 15 μm and 90 μm. The compliant material is selected to have a high modulus and a low CTE approaching the CTE of the semiconductor chips; it may be glass filled and may include liquid crystal polymers.

In the next process step, designated 392 in FIG. 3, a grinding technology is used to grind the insulating lamination material 320 uniformly until the tops of the metal bumps 302 are exposed. The grinding process may continue by removing some bump height until bumps 302 are flat with the planar surface of lamination material 330; preferably, the remaining bump height 302a is between about 25 and 50 μm. Thereafter, carrier 320 is secured in a frame to restrain warpage and is transferred, with its assembly, to the vacuum and plasma chamber of an apparatus for sputtering metals.

During the processes summarized in step 393, the assembly of carrier 320, with the exposed metal bumps and lamination surfaces, is plasma-cleaned, while the panel is cooled, preferably below ambient temperature. The plasma accomplishes, besides cleaning the surface from adsorbed films, especially water monolayers, some roughening of the surfaces; both effects enhance the adhesion of the sputtered metal layer. Then, at uniform energy and rate, at least one layer 340a of metal is sputtered onto the exposed bump and lamination surfaces across the carrier. The sputtered layer is adhering to the surfaces.

Preferably, the step of sputtering includes the sputtering of a first layer of a metal selected from a group including titanium, tungsten, tantalum, zirconium, chromium, molybdenum, and alloys thereof, wherein the first layer is adhering to chip and lamination surfaces; and without delay sputtering at least one second layer of a metal selected from a group including copper, silver, gold, and alloys thereof, onto the first layer, wherein the second layer is adhering to the first layer. The sputtered layers have the uniformity, strong adhesion, and low resistivity needed to serve, after patterning, as conductive traces for rerouting; the sputtered layers may also serve as seed metal for plated thicker metal layers.

In optional step 394, at least one layer 340b of metal is electroplated onto the sputtered layers 340a. A preferred metal is copper. The plated layer is preferably thicker than the sputtered metal to lower the sheet resistance and thus the resistivity of the rerouting traces after patterning the plated and sputtered metal layers. The steps of patterning the sputtered and plated metal layers in order to create connecting traces between the bumps and enlarged package contact pads are preferably executed with a laser direct-imaging technology.

In addition, it is preferred, in step 395, to deposit and pattern rigid insulating material 360, such as so-called solder resist, to protect and strengthen remaining chip areas not used for extended contacts and between the rerouting traces. In order to apply solder resist and other dielectric materials, photo-imagable materials, etchants, and others, a preferred technique uses an ultrasonic spray tool. In the next process step 396, panel-size carrier 320 is singulated into discrete devices 370; the preferred separating technique is sawing. After singulation, respective parts 321 of carrier 320 remain with the finished packages of devices 370.

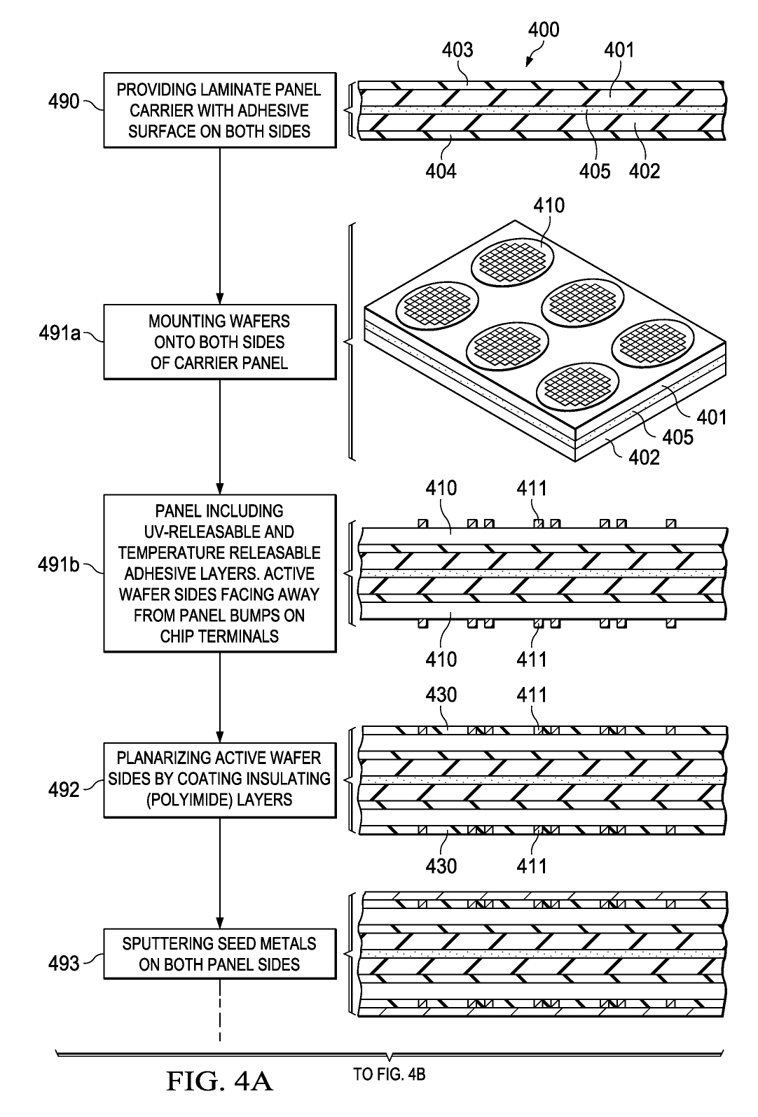

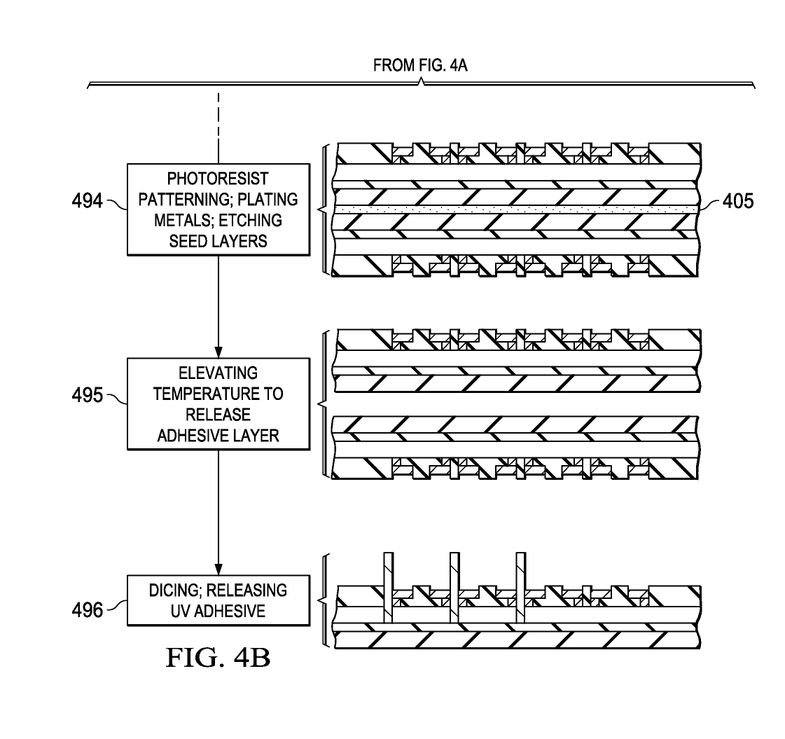

Another embodiment is a method for fabricating packaged semiconductor devices in panel format, illustrated in FIGS. 4A and 4B. The method starts in step 490 by providing a panel sheet 400 as a carrier having an exemplary size of about 12″ by 25″. The carrier is made of cores 401 and 402 of a clear laminate material. Cores 401 and 402 are bisected by a layer 405 of temperature-releasable first adhesive. The cores have surfaces covered by tacky coats 403 and 404, respectively, with a second adhesive so that a plurality of wafers with diameters between 8″ and 12″ can be attached to either one or both carrier sides. The second adhesive is UV sensitive so that it can be released by UV irradiation. The symmetry of panel 400 is suitable for executing certain process steps on both panel sides concurrently.

In addition, whole semiconductor wafers 410 are provided, which incorporate a plurality of devices and circuits. The devices and circuits preferably have bondpads and terminals with metal bumps such as copper pillars (for example about 200 μm high).

In process step 491 (in FIG. 4A, steps 491a and 492b combined), at least one wafer 410 is attached on the second adhesive of at least one side of panel 400, the active wafer side and the circuit terminals with bumps 411 are facing away from the respective panel surface. Preferably, a plurality of wafers 410 is attached on each tacky side of panel 400.

Next (step 492), the wafer surfaces on each panel side are uniformly coated with an insulating material 430, filling the gaps between the terminal bumps 411. The step of coating employs an ultrasonic spray apparatus suitable for uniformly spraying insulating materials selected from a group including polyimides, photo-image-able compounds, and dielectric spin-on compounds. Thereafter, panel 400, with wafers attached on both sides, is transferred to the vacuum and plasma chamber of a sputtering equipment.

During the processes summarized in step 493, panel 400 with the exposed metal bumps 411 and surfaces of coat 430, is plasma-cleaned. The plasma accomplishes, besides cleaning the surface from adsorbed films, especially water monolayers, some roughening of the surfaces; both effects enhance the adhesion of the sputtered metal layer. Then, at uniform energy and rate and while the panel is cooled from the back side, at least one layer 340a of metal is sputtered onto the exposed bump and coat surfaces on each panel side. The sputtered layer is adhering to the surfaces. As stated above in a previous method, the metal of the at least one sputtered layer is preferably a refractory metal; it is further preferred that a second sputtered layer, preferably including copper, is added onto the first layer without delay.

In step 494, the optional next processes of plating, patterning, and etching are performed in a manner analogous to the processes described above in a previous method. In addition, an optional deposition and patterning of a protecting solder resist layer is similar to previously described processes.

In step 495, the temperature is elevated to release adhesive layer 405 so that panel cores 401 and 402 can be separated. Thereafter in step 496, the wafers, supported by their respective panel cores, are individually diced. After the respective panel cores have been released by UV irradiation, discrete packaged semiconductor devices have been created. The devices have the technical advantage that the exposed back sides of the semiconductor chips can serve as excellent heat spreaders.

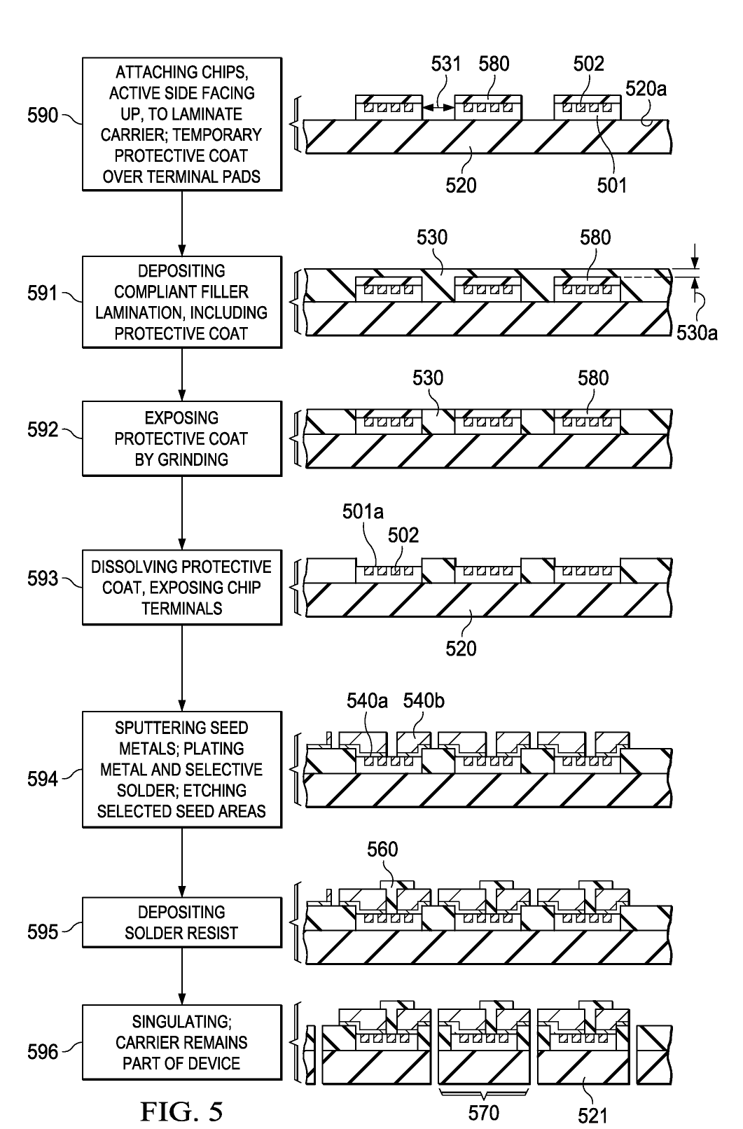

Another embodiment is an exemplary method for fabricating packaged semiconductor devices in panel format, illustrated in FIG. 5. The method starts by selecting a laminate rigid carrier 520 with a dielectric and tacky-coated surface 520a (adhesive may also be spray-coated or laminated). The carrier has panel size, i.e., lateral dimensions larger than at least one semiconductor wafer, and is thus suitable for the attachment of a large number of semiconductor chips. The composition of carrier 520 is such that its material can become a permanent part of the final packaged devices. Furthermore, semiconductor chips 501 (of exemplary thickness of about 150 μm) are provided, where the terminal pads 502 of the devices on a chip surface have a temporary, i.e. removable or dissolvable, protective coat 580. It is preferred that coat 580 is applied over the entire surface of a whole wafer and is left on during wafer dicing. In some devices, there may be another inert film, such as polyimide, under the protective coat.

In process step 590 of FIG. 5, a plurality of semiconductor chips 501 with protective coat 580 is attached onto the dielectric surface 520a of panel sheet 520 as a carrier. The chips are oriented so that terminal pads 502 and protective coat 580 face away from the panel surface. Preferably, a plurality of chips is aligned in an orderly array or grid, wherein chips 501 are spaced from each other by gaps 531.

In step 591, a compliant insulating material 530 is laminated, under vacuum suction, in order to cohesively fill any gaps 531 between the chips and to cover the protective coats 580. Preferably, the height 530a of the laminated material over the coat tops is between about 15 μm and 50 μm. The compliant material is selected to have a high modulus and a low CTE approaching the CTE of the semiconductor chips; it may be glass filled and may include liquid crystal polymers.

In the next process step, designated 592 in FIG. 5, a grinding technology is used to grind the insulating lamination material 530 uniformly until the tops of the protective coats 580 are exposed. The grinding process may continue by removing approximately one half of the protective coat 580 with a target height of about 10 μm or less above the chip surface. As a result, protective coat 580 forms a planar surface with lamination material 530.

In process step 593, the protective coat over the chip surface and terminals is removed, for instance by etching or in a water wash. This step exposes chip surface 501a and the chip terminals 502. Thereafter, carrier 520 is secured in a frame to restrain warpage and is transferred, with its assembled chips, to the vacuum and plasma chamber of an apparatus for sputtering metals.

During the processes summarized in step 594, the assembly of carrier 520, with the exposed chip terminals and lamination surfaces, is plasma-cleaned, while the panel is cooled, preferably below ambient temperature. Then, at uniform energy and rate, at least one layer 540a of metal is sputtered as seed metal onto the exposed chip terminals and lamination surfaces across all chips assembled on the carrier. The sputtered layer is adhering to the surfaces. As stated in more detail in a previous method, the step of sputtering preferably includes the sputtering of a first layer of a metal selected from refractory metals, followed without delay by the sputtering of at least one second layer of a metal, preferably copper. The sputtered layers have the uniformity, strong adhesion, and low resistivity needed to serve, after patterning, as conductive traces for rerouting; the sputtered layers may also serve as seed metal for plated thicker metal layers.

Further included in step 594 is the step of plating at least one layer 540b of metal onto the sputtered layers 540a. A preferred plated metal is copper. The plated layer is preferably thicker than the sputtered metal to lower the sheet resistance and thus the resistivity of the rerouting traces after patterning the plated and sputtered metal layers. The step of patterning the sputtered and plated metal layers is also included in step 594; the step creates connecting traces between the bumps and enlarged package contact pads and is preferably executed with a laser direct-imaging technology. The laser direct-imaging technology uses an out-alignment correcting technique.

In addition, it is preferred, in step 595, to deposit and pattern rigid insulating material 560, such as so-called solder resist, to protect and strengthen remaining chip areas not used for extended contacts and between the rerouting traces. In order to apply solder resist and other dielectric materials, photo-imagable materials, etchants, and others, a preferred technique uses an ultrasonic spray tool. In the next process step 596, panel-size carrier 520 is singulated into discrete devices 570; the preferred separating technique is sawing. After singulation, respective parts 521 of carrier 520 remain with the finished packages of devices 570.

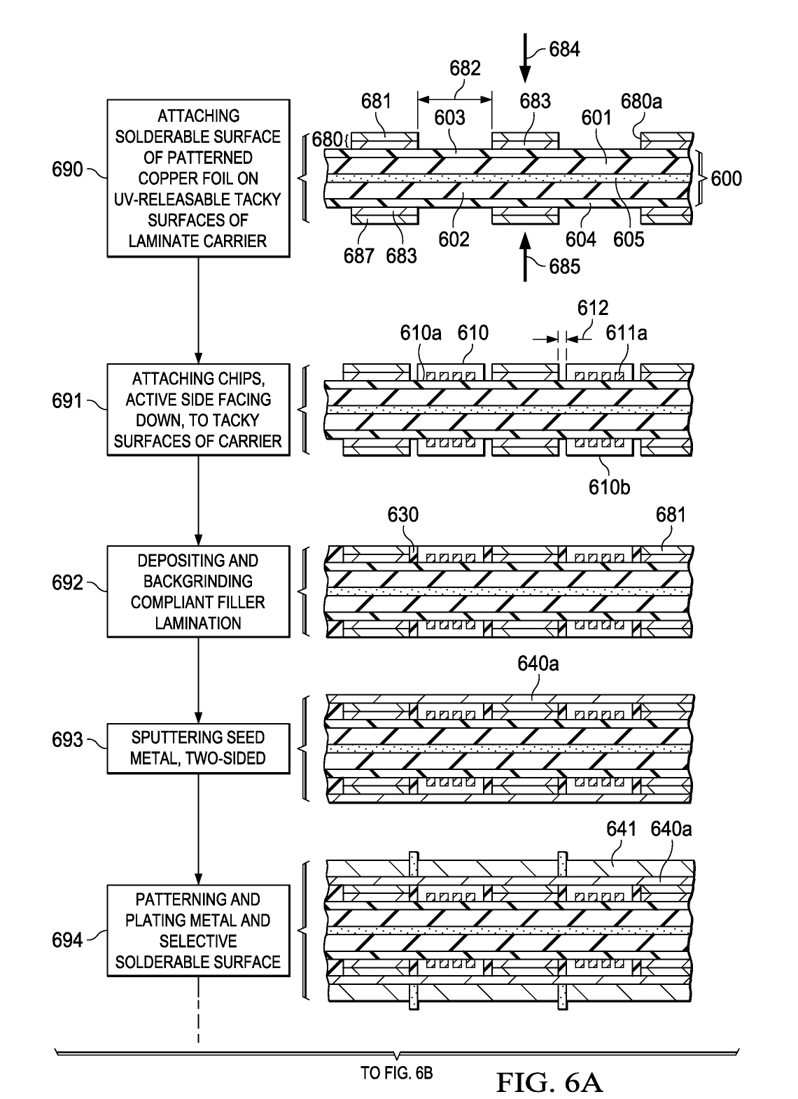

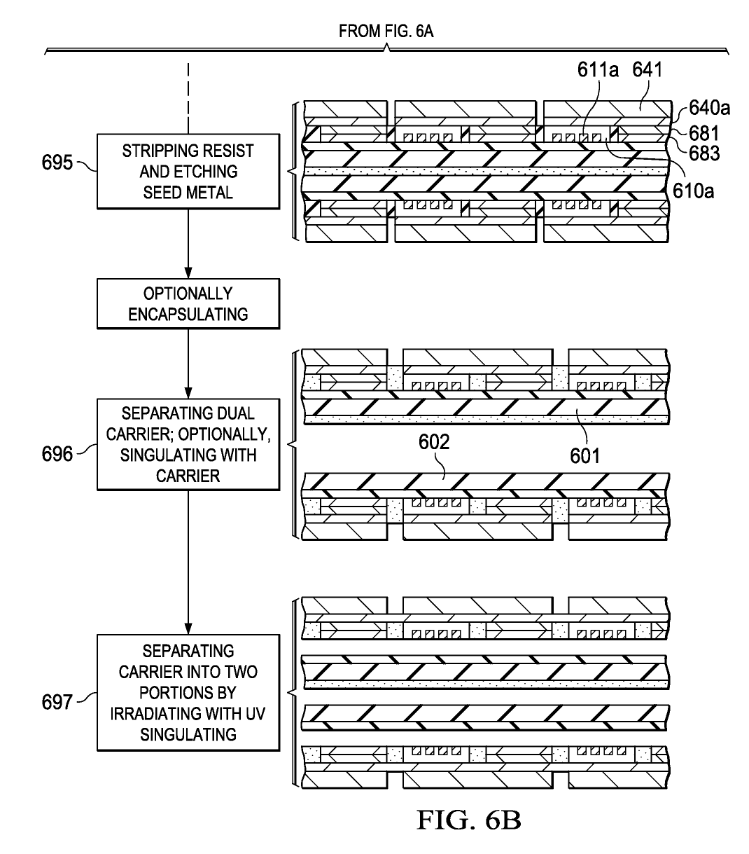

Another embodiment is a method for fabricating packaged semiconductor devices in panel format, illustrated in FIGS. 6A and 6B. The method starts by providing a panel sheet 600 as a carrier. Carrier 600 is made of cores 601 and 602 of a clear laminate material. Cores 601 and 602 are bisected by a layer 605 of temperature-releasable first adhesive. The cores have surfaces covered by tacky coats 603 and 604, respectively, with a second adhesive so that a plurality of semiconductor chips can be attached to either one or both carrier sides. The second adhesive is UV sensitive so that it can be released by UV irradiation. The symmetry of the panel is suitable for executing certain process steps on both panel sides concurrently.

In process step 690, a metallic grid is provided which includes a plurality of metal rims 680 spaced by openings 682. Rims 680 are often referred to as fiducials; the sidewalls 680a of the fiducials are facing the openings 682. The preferred metal 681 of the rims is copper; one surface 683 of each rim has a solderable surface. One method for fabricating the grid is to provide a window frame of a sheet metal, which has one solderable surface, and then to form the array of openings by stamping or etching. In an alternative method, metal foils are laminated on both layers 603 and 604 of the second adhesive, with the respective solderable foil surfaces facing the adhesive layer. The metal foils are then patterned to create a plurality of fiducials to mark the openings 682 suitable for semiconductor chips. In step 690, a metallic grid is attached to at least one tachy side of carrier 600, as indicated by arrows 684 and 685, respectively; in exemplary FIG. 6A, both sides of carrier 600 are populated by a metal grid.

In process step 691, a plurality of semiconductor chips 610 is attached to the tacky layers on the surfaces of carrier 600 within the respective openings 682 between adjacent fiducials. Chips 610 are spaced from fiducials sidewalls 680a by gaps 612. The chips have a surface 610a with first terminals 611a facing the respective adhesive layer, and a second surface 610b with second terminals facing away from the respective adhesive layer. As an example, the chips may be power field effect transistors (FETs).

Several processes are summarized in step 692 of FIG. 6A. The gaps 612 between chips and fiducuals sidewall are cohesively filled by a process, in which, under vacuum suction, a compliant insulating material 630 is laminated, thereby forming an assembly with a planar surface with the back surface 610b of the chips. The compliant material is selected so that it exhibits a high modulus and low coefficient of thermal expansion (CTE) approaching the CTE of the semiconductor chips. It is an option to use a leveling or grinding technique to remove lamination material 630 and fiducial metal 681 until proper planarity with the second chip terminals is achieved.

Thereafter, panel 600, with wafers attached on both sides, is transferred to the vacuum and plasma chamber of a sputtering equipment. In step 693, both sides of panel 600 are plasma-cleaned. The plasma accomplishes, besides cleaning the surface from adsorbed films, especially water monolayers, some roughening of the surfaces; both effects enhance the adhesion of the sputtered metal layer. Then, at uniform energy and rate and while the panel is cooled from the back side, at least one layer 640a of metal is sputtered onto the exposed chip, fiducial, and lamination surfaces on each panel side. The sputtered layer is adhering to the surfaces. As stated above in a previous method, the metal of the at least one sputtered layer is preferably a refractory metal; it is further preferred that a second sputtered layer, preferably including copper, is added onto the first layer without delay.

In steps 694 and 695, the optional next processes of plating, patterning, etching, and photoresist removal of additional metal layers, such as copper, are performed in a manner analogous to the processes described above in a previous method. Furthermore, seed metal layers 640a are patterned. As a result of the patterning of plated and sputtered layers 641 and 640a, rerouting traces are created, which allow a redistribution of the second chip terminals from the second surface 610b to the surface 610a of the first terminals 611a.

After an optional encapsulation process between step 695 and step 696, the temperature is elevated to release layer 605 of the first adhesive so that panel cores 601 and 602 can be separated. Then, UV irradiation is initiated to release the layers 603 and 604 of the second adhesive and thus to separate the assembled strips of chips from the respective carriers. Thereafter in step 697, the device strips with their metallization-enhanced chips are individually diced. The devices have the technical advantage that the metallized back sides of the semiconductor chips can serve as excellent heat spreaders.

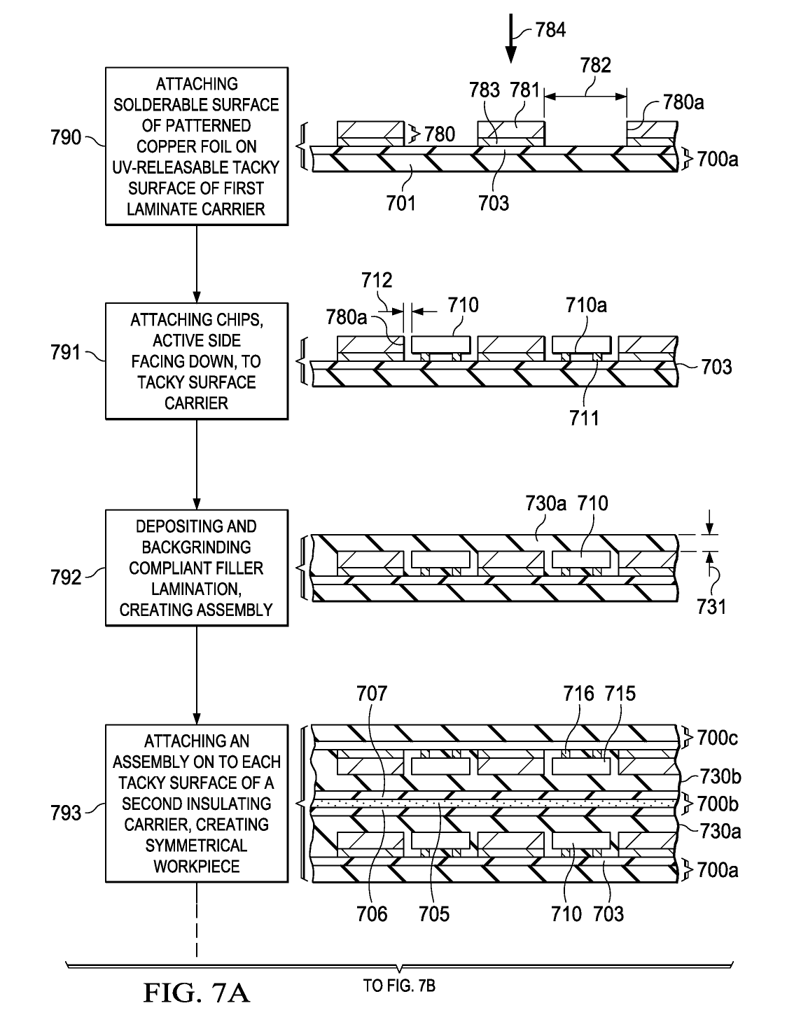

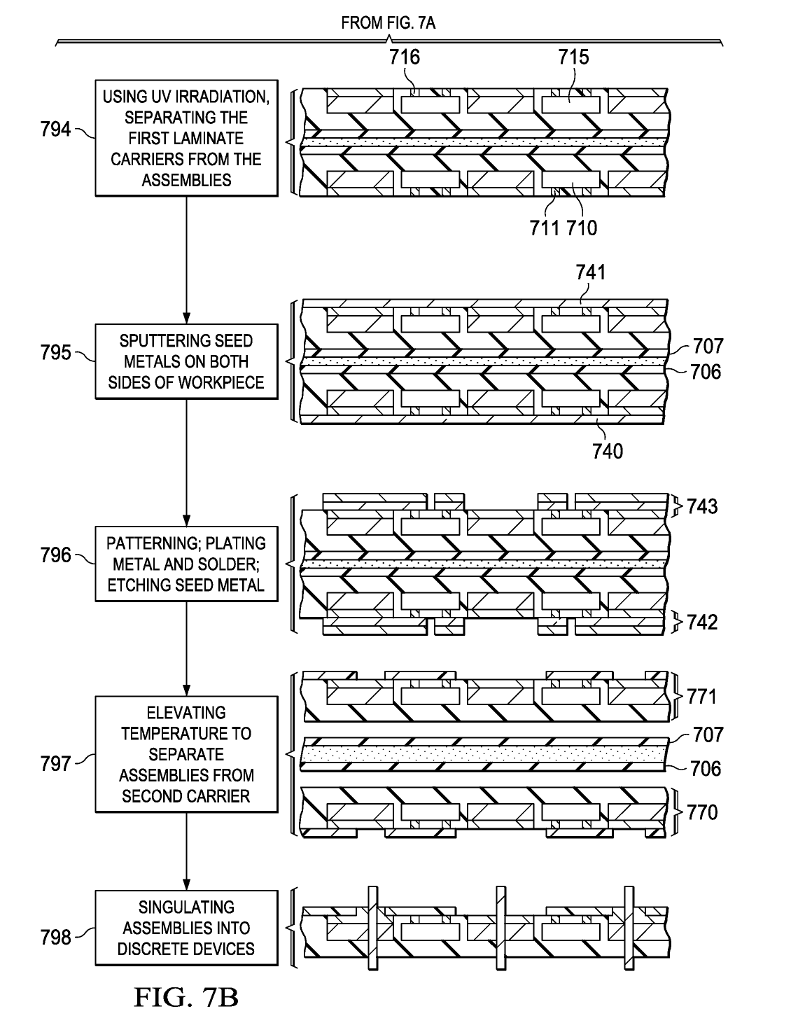

Another embodiment is a method for fabricating packaged semiconductor devices in panel format, illustrated in FIGS. 7A and 7B. The method starts by providing a first panel sheet 700a as a carrier. Carrier 700a is made of an insulating core 701 of a clear laminate material. Core 701 has a surface covered by a tacky coat 703 with a first adhesive, which is UV sensitive so that it can be released by UV irradiation.

In process step 790, a metallic grid is provided which includes a plurality of metal rims 780 spaced by openings 782. Rims 780 are often referred to as fiducials; the sidewalls 780a of the fiducials are facing the openings 782. The preferred metal 781 of the rims is copper; one surface 783 of each rim has a solderable surface. One method for fabricating the grid is to provide a window frame of a sheet metal, which has one solderable surface, and then to form the array of openings by stamping or etching. In an alternative method, a metal foil is laminated on layer 703 of the first adhesive, with the solderable foil surface facing the adhesive layer. The metal foil is then patterned to create a plurality of fiducials to mark the openings 782 suitable for semiconductor chips. In step 790, the metallic grid is attached to the tacky side of carrier 700a, as indicated by arrows 784.

In process step 791, a plurality of semiconductor chips 710 is attached to the tacky layer on the surface of carrier 700a within the respective openings 782 between adjacent fiducials. Chips 710 are spaced from fiducials sidewalls 780a by gaps 712. The chips have a surface 710a with terminals 711 facing the adhesive layer 703; for many chip types, their terminals have metal bumps.

Several processes are summarized in step 792 of FIG. 7A. The gaps 712 between chips and fiducials sidewall are cohesively filled by a process, in which, under vacuum suction, a compliant insulating material 730a is laminated. The thickness of material 730a reaches a height 731 over the back side of chips 710. The compliant material is selected so that it exhibits a high modulus and low coefficient of thermal expansion (CTE) approaching the CTE of the semiconductor chips. It is an option to use a leveling or grinding technique to remove lamination material 630a surpassing height 731.

For step 793, a second panel, or carrier, 700b is provided, which has an insulating core 705. On both surfaces of core 705 is a tacky film, designated 706 and 707 in FIG. 7A, made of a temperature-releasable second adhesive. In step 793, the surface of first panel 700a with the compliant insulating material 730a is attached to an adhesive surface layer 706 of second panel 700b. In addition, the surface of a third panel 700c (chips designated 715) with the compliant insulating material 730b is attached to adhesive surface layer 707 of third panel 700c. In this fashion, a symmetrical workpiece is created.

Thereafter, in step 794 UV-irradiation is used on the first adhesives of both sides of the workpiece. Laminate carriers 700a and 700c are thus separated from the assemblies on both sides of the workpiece, and the surfaces of chips 710 and 715 with the terminals 711 and 716 (and their bumps), respectively, are exposed.

In step 795, the remainder of the workpiece with chips 710 and 715 attached on both sides, is transferred to the vacuum and plasma chamber of a sputtering equipment. In step 795, both sides of the workpiece are plasma-cleaned. The plasma accomplishes, besides cleaning the surface from adsorbed films, especially water monolayers, some roughening of the surfaces; both effects enhance the adhesion of the sputtered metal layer. Then, at uniform energy and rate and while the panel is cooled from the back side, at least one layer 740 and 741, respectively, of metal is sputtered onto the exposed chips, fiducial, and lamination surfaces on each panel side. The sputtered layer is adhering to the surfaces. As stated above in a previous method, the metal of the at least one sputtered layer is preferably a refractory metal; it is further preferred that a second sputtered layer, preferably including copper, is added onto the first layer without delay.

In step 796, the optional next processes of plating, patterning, etching, and photoresist removal of additional metal layers 742 and 743, such as copper, are performed in a manner analogous to the processes described above in a previous method. Furthermore, seed metal layers 740 and 741 are patterned. As a result of the patterning of plated and sputtered layers, rerouting traces are created; both sides of the workpiece have completed assemblies.

After an optional encapsulation process before step 797, the temperature is elevated to release layers 706 and 707 of the second adhesive so that the assemblies 770 and 771 on both sides of the second panel, or carrier, can be separated. Thereafter in step 798, the device strips with their metallization-enhanced chips are individually diced.

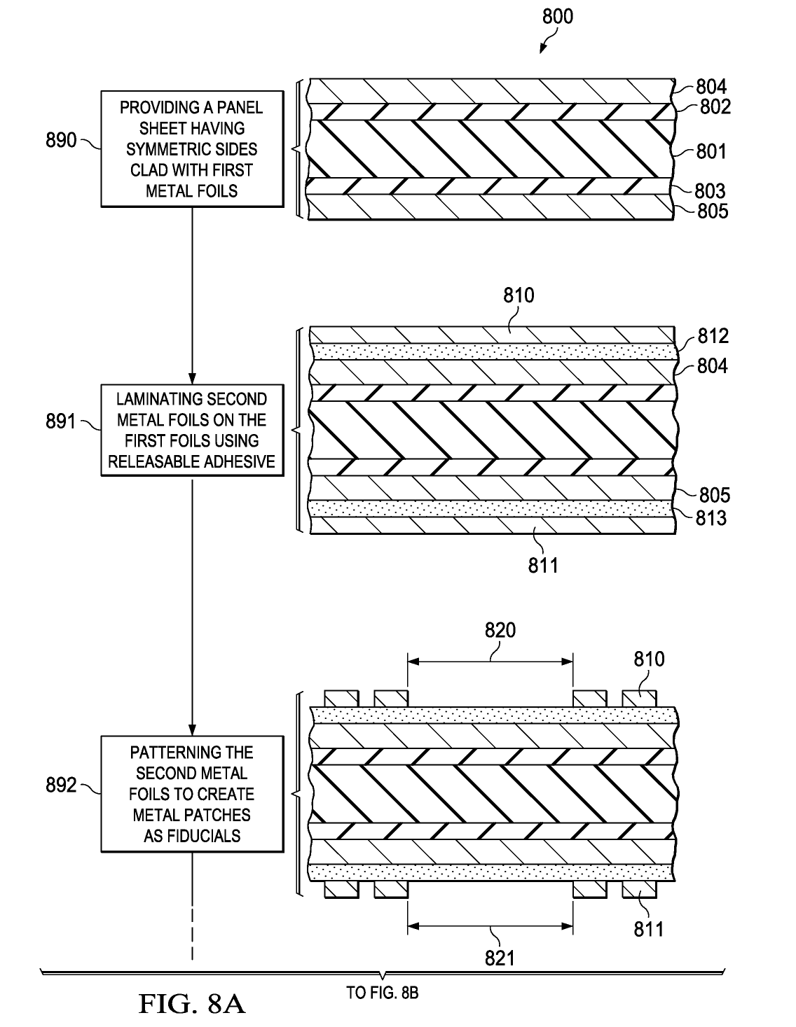

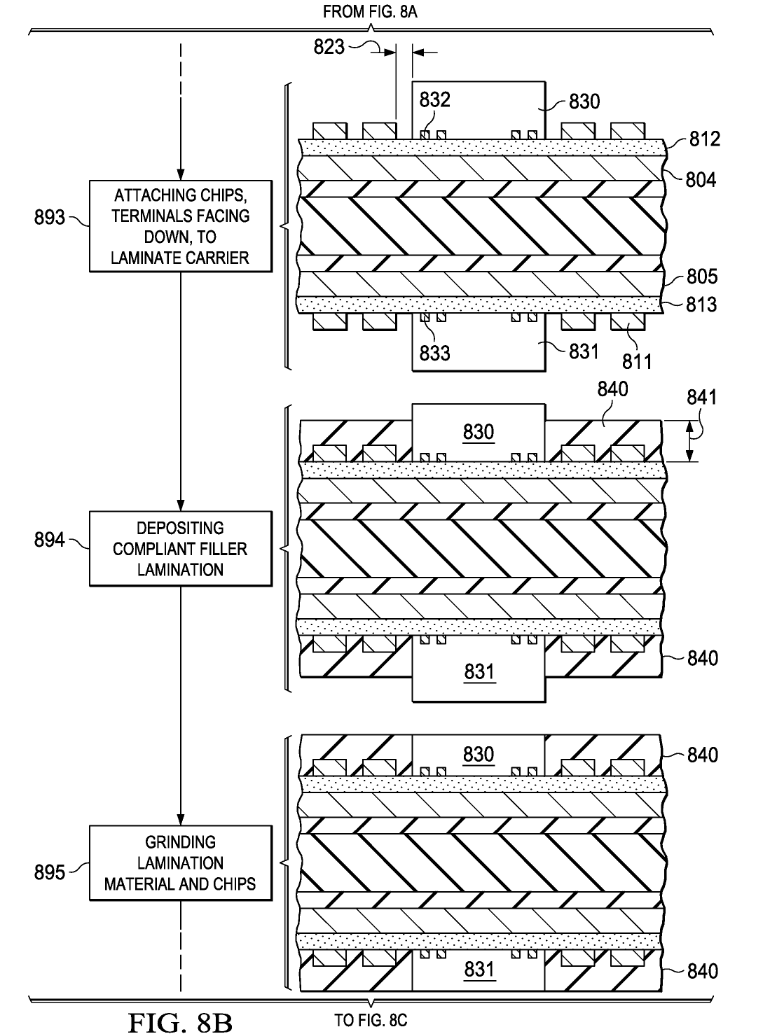

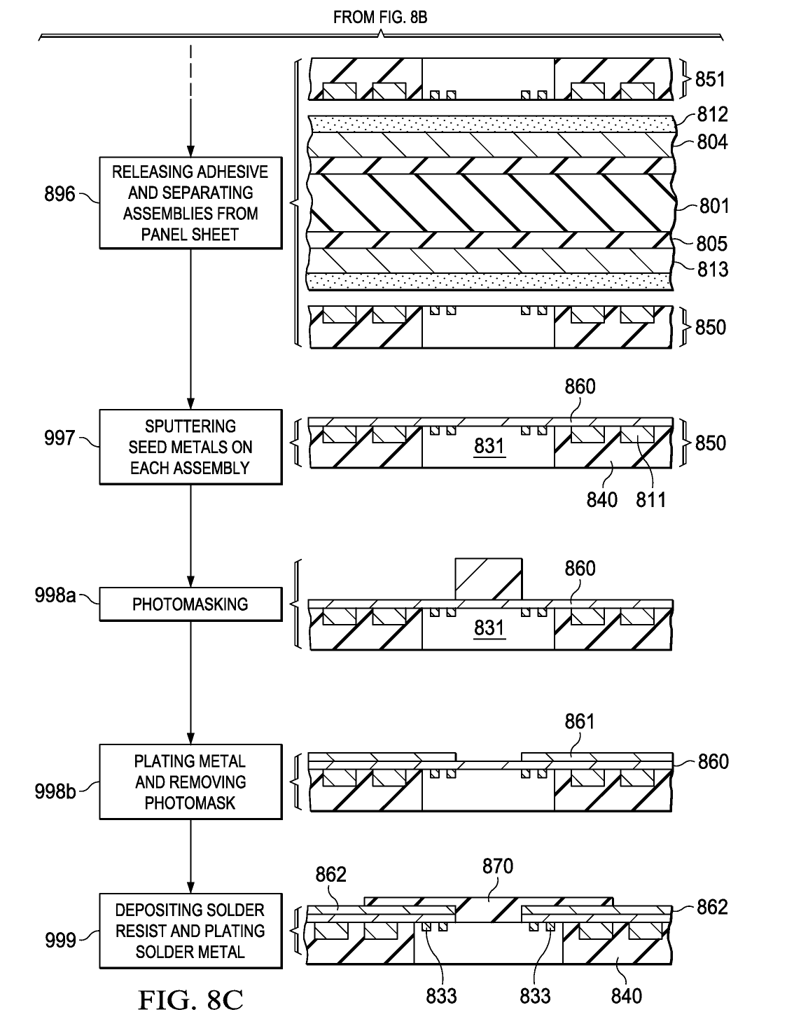

Another embodiment is a method for fabricating packaged semiconductor devices in panel format, illustrated in FIGS. 8A to 8C. The method starts at step 890 by providing a panel sheet 800 as a carrier, which has an insulating core 801 with a layer of first adhesive covering each side, designated 802 and 803 in FIG. 8A, and first metal foils 804 and 805 adhering to the adhesive layers, respectively. The symmetry of panel 800 has the technical advantage that it allows to execute certain process steps on both panel sides concurrently.

In the next process step 891, second metal foils 810 and 811 are laminated to the first metal foils 804 and 805, respectively, by using layers 812 and 813 of a second adhesive, which is releasable at elevated temperature. Exemplary second metal foils may be made of copper at a thickness of about 3 μm. In step 892, second metal foils 810 and 811 are patterned in order to create a plurality of fiducials, which are used to mark spaces 820 and 821 reserved for attaching semiconductor chips.

In process step 893, a plurality of semiconductor chips 830 and 831 is attached to the second adhesive 812 and 813 on the first metal 804 and 805 within the reserved spaces 820 and 821, respectively. Chips 830 and 831 are oriented so that the chip terminals 832 and 833 face the respective second adhesive layer.

In process step 894 of FIG. 8B, any gaps 823 between chips and fiducuals are cohesively filled by a process, in which, under vacuum suction, a compliant insulating material 840 is laminated. The thickness of material 840 reaches a height 841, which may be greater or smaller than the back side of chips 830 and 831. The compliant material is selected so that it exhibits a high modulus and low coefficient of thermal expansion (CTE) approaching the CTE of the semiconductor chips. The step of laminating is embedding the fiducials in the compliant insulating material.

In process step 895, lamination material 840 and chips 830 and 831 are flattened uniformly by a leveling or grinding method until both the lamination material and the chip back sides have a planar surface across the panel. By this leveling process, the assemblies on both sides of the panel are completed and have planar surfaces.

In process step 896, the temperature is elevated to release the second adhesive of layers 812 and 813 on both sides of the panel and thus enable the separation of the panel core 801 with its adhering first metal foils 804 and 805 and layers 812 and 813 of second adhesives from the assemblies 850 and 851 on both panel sides. Each assembly is now freed to be processed separately. FIG. 1C illustrates certain process steps to be performed on each panel-sized assembly. For step 897, each assembly is transferred to the vacuum and plasma chamber of an apparatus for sputtering metals.

During the processes summarized in step 997, the exposed terminal pads 833, lamination 840, chip 831, and fiducials 811 of panel 850 are plasma-cleaned. The plasma accomplishes, besides cleaning the surface from adsorbed films, especially water monolayers, some roughening of the surfaces; both effects enhance the adhesion of the sputtered metal layer. Then, at uniform energy and rate and while the panel is cooled from the back side, at least one layer 860 of metal is sputtered onto the exposed surfaces across the panel. The sputtered layer is adhering to the surfaces.

Preferably, the step of sputtering includes the sputtering of a first layer of a metal selected from a group including titanium, tungsten, tantalum, zirconium, chromium, molybdenum, and alloys thereof, wherein the first layer is adhering to chip and lamination surfaces; and without delay sputtering at least one second layer of a metal selected from a group including copper, silver, gold, and alloys thereof, onto the first layer, wherein the second layer is adhering to the first layer. The sputtered layers have the uniformity, strong adhesion, and low resistivity needed to serve, after patterning, as conductive traces for rerouting; the sputtered layers may also serve as seed metal for plated thicker metal layers.

After photomasking portions of chip 831 in step 998a, in optional step 998b at least one layer 861 of metal is electroplated onto the sputtered layers 860. A preferred metal is copper for its good conductivity. Next, step 999 in FIG. 8C illustrates the processes of patterning the sputtered and plated metal layers in order to create connecting traces between chip terminal pads 833 and enlarged contact pads 862, which are positioned over the laminated material 840. As FIG. 8C shows, the connecting traces are anchored in the fiducials. Contact pads 862 may receive an additional plating with tin or another solderable metal. It is preferred to execute the step of patterning with a laser direct-imaging technology.

In addition, it is preferred to deposit and pattern rigid insulating material 870, such as so-called solder resist, to protect and strengthen remaining chip areas not used for extended contacts and between the rerouting traces. In order to apply solder resist and other dielectric materials, photo-imagable materials, etchants, and others, a preferred technique uses an ultrasonic spray tool.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

We claim:

1. A method for fabricating packaged semiconductor devices in panel format, comprising
placing a metallic grid onto an adhesive tape, the grid having a plurality of openings framed by metal rims with sidewalls, each opening sized to accommodate one or more discrete semiconductor chips;
placing semiconductor chips inside each opening, the chips spaced by gaps between adjacent chips and sidewalls, and attaching the chips onto the adhesive tape with the metallized terminals facing the tape, the chips coated with a layer of insulating inert polymer, the layer having openings to expose chip terminals;
laminating, under vacuum suction, a compliant insulating material to cohesively fill the gaps between adjacent chips and sidewalls, thereby forming an assembly with a planar surface, the material having a coefficient of thermal expansion approaching the coefficient of the semiconductor chips;
placing a carrier sheet over the assembly and attaching the sheet to the planar surface;
turning over the metallic grid with the assembly so that the adhesive tape is facing up for removing the tape and exposing the coats and terminals of the chip surfaces;
plasma-cleaning, in an equipment for sputtering metals, the exposed chip and lamination surfaces;
sputtering, at uniform energy and rate and while cooling the assembly, at least one layer of metal onto the exposed chip and lamination surfaces, the layer adhering to the surfaces; and
patterning the metal layers to create conductive rerouting traces between chip terminals and extended contact pads located over laminated material.

2. The method of claim 1 wherein sputtering includes the sputtering of a first layer of a metal selected from a group including titanium, tungsten, tantalum, zirconium, chromium, molybdenum, and alloys thereof, the first layer adhering to chip and lamination surfaces; and without delay sputtering at least one second layer of a metal selected from a group including copper, silver, gold, and alloys thereof, onto the first layer, the second layer adhering to the first layer.

3. The method of claim 2, wherein patterning uses a laser direct imaging technology.

4. The method of claim 3 wherein the laser direct imaging technology uses an out-alignment correcting technique.

5. The method of claim 4 further comprising, after sputtering and before patterning, plating a layer of metal onto the sputtered layer of metal.

6. The method of claim 1 further comprising, after patterning, depositing and patterning rigid insulating material onto the surface portions not used for the extended contacts.

7. The method of claim 6 wherein the rigid insulating material is solder mask.

8. The method of claim 1 wherein the inert insulating material includes polyimide.

9. The method of claim 1 wherein the adhesive tape is a silicone-based tacky tape.

10. The method of claim 1 wherein the carrier film is an impregnated carrier film.

11. The method of claim 1 wherein the metallized terminals include metal bumps.

12. A method for fabricating packaged semiconductor devices in panel format, comprising:
attaching a plurality of semiconductor chips onto the dielectric surface of a panel sheet as a carrier, the chip bondpads having metal bumps, the bondpads facing away from the panel surface;
laminating, under vacuum suction, a compliant insulating material to cohesively fill gaps between the chips and to cover the chip bondpad bumps, the material having a coefficient of thermal expansion approaching the coefficient of the semiconductor chips;
grinding lamination material uniformly until the tops of the metal bumps are exposed;
securing the panel in a frame to restrain warpage;
plasma-cleaning, in an equipment for sputtering metals, the exposed metal bumps and lamination surfaces; and
sputtering, at uniform energy and rate and while cooling the panel, at least one layer of metal onto the exposed lamination and bumps, the layer adhering to the surfaces.

13. The method of claim 12 wherein sputtering includes the sputtering of a first layer of a metal selected from a group including titanium, tungsten, tantalum, zirconium, chromium, molybdenum, and alloys thereof, the first layer adhering to chip and lamination surfaces; and without delay sputtering at least one second layer of a metal selected from a group including copper, silver, gold, and alloys thereof, onto the first layer, the second layer adhering to the first layer.

14. The method of claim 13 further comprising:
plating and patterning a layer of the second metal onto the sputtered layer of the second metal;
plating a layer of solderable metal onto selected areas of the plated second metal;
stripping selected areas of the sputtered metal layers;
depositing and patterning insulating material over selected areas of the plated second metal; and
dicing the panel to singulate discrete devices, retaining the cut panel as part of each discrete device.

15. The method of claim 12 wherein the panel sheet has lateral dimensions larger than at least one semiconductor wafer.

16. A method for fabricating packaged semiconductor devices in panel format, comprising:
providing a panel sheet as a carrier having an insulating core of clear laminate material bisected by a layer of temperature-releasable first adhesive, and two surfaces covered by layers of UV-releasable second adhesive, the symmetry of the panel suitable for executing certain process steps on both panel sides concurrently;
providing semiconductor wafers incorporating a plurality of devices and circuits having terminals with metal bumps;
attaching at least one wafer on the second adhesive of at least one side of the panel, the bumped terminals facing away from the respective panel surface;
coating the wafer surface uniformly with an insulating material, filling the gaps between the terminal bumps;
plasma-cleaning both panel sides and attached wafers uniformly in an equipment for sputtering metals; and
sputtering, at uniform energy and rate and while cooling the panel, onto the insulating coats of both panel sides a layer of a first metal adhering to the coats and the terminals, and without delay, further sputtering a layer of a second metal onto the first layer, the second metal adhering to the first metal.

17. The method of claim 16, wherein coating employs an ultrasonic spray apparatus suitable for uniformly spraying insulating materials selected from a group including polyimides, photo-image-able compounds, and dielectric spin-on compounds.

18. The method of claim 17 further comprising:
patterning and plating a layer of the second metal onto the sputtered layer of the second metal;
plating a layer of solderable metal onto selected areas of the plated second metal;
etching selected areas of the sputtered metal layers, thereby completing the assembly on both panel sides;
elevating the temperature to release the first adhesive and thus enable the separation of the assembled panel sides with their respective panel cores;
dicing the assembled panel sides to singulate discrete devices; and
using UV-irradiation to release the discrete devices from the respective panel core.

19. A method for fabricating packaged semiconductor devices in panel format, comprising:
attaching a plurality of semiconductor chips onto the adhesive surface of a rigid sheet as a carrier, the metallized chip terminals covered by a removable coat and facing away from the panel surface;
laminating, under vacuum suction, a compliant insulating material to cohesively fill gaps between the chips and to cover chips and coats, the material having a coefficient of thermal expansion approaching the coefficient of the semiconductor chips;
grinding lamination material uniformly until the tops of the coats are exposed;
removing the chip coats to expose the metallized chip terminals;
securing the panel in a frame to restrain warpage;
plasma-cleaning, in an equipment for sputtering metals, the exposed chip, bondpad and lamination surfaces; and
sputtering, at uniform energy and rate and while cooling the panel, at least one layer of metal onto the exposed lamination and metallized bondpads, the layer adhering to the surfaces.

20. The method of claim 19 wherein sputtering includes the sputtering of a first layer of a metal selected from a group including titanium, tungsten, tantalum, zirconium, chromium, molybdenum, and alloys thereof, the first layer adhering to chip and lamination surfaces; and without delay sputtering at least one second layer of a metal selected from a group including copper, silver, gold, and alloys thereof, onto the first layer, the second layer adhering to the first layer.

21. The method of claim 20 further comprising:
plating and patterning a layer of the second metal onto the sputtered layer of the second metal;
plating a layer of solderable metal onto selected areas of the plated second metal;
stripping selected areas of the sputtered metal layers;
depositing and patterning insulating material over selected areas of the plated second metal, enhancing rigidity; and
dicing the panel to singulate discrete devices, retaining the cut panel as part of each discrete device.

22. The method of claim 19 wherein removing the chip coats involves a dissolving method.

23. The method of claim 19 wherein removing the chip coats involves a grinding method followed by an etching or washing method.

24. A method for fabricating packaged semiconductor devices in panel format, comprising:
providing a panel sheet as a carrier having an insulating core of clear laminate material bisected by a layer of temperature-releasable first adhesive, and two surfaces covered by layers of UV-releasable second adhesive, the symmetry of the panel suitable for executing certain process steps on both panel sides concurrently;
placing the solderable surface of a metallic grid on each layer of second adhesive, the grid having a plurality of openings framed by fiducials with sidewalls, each opening sized to accommodate a semiconductor chip;
attaching a plurality of semiconductor chips to adhesive panel surfaces within respective openings, the chips having first terminals facing the adhesive surface and second terminals facing away from the adhesive surface;
laminating, under vacuum suction, a compliant insulating material to cohesively fill gaps between chips and fiducials, the material having a coefficient of thermal expansion approaching the coefficient of the semiconductor chips;
grinding lamination material and fiducials uniformly until they form a plane with the second terminals;
plasma-cleaning both panel sides and attached chips uniformly in an equipment for sputtering metals; and
sputtering, at uniform energy and rate and while cooling the panel, onto each panel side at least one layer of metal adhering to the planar surfaces of second chip terminals, fiducials, and insulating material.

25. The method of claim 24 wherein the metallic grid is created by laminating a metal foil on each layer of second adhesive, the foils having a surface with solderabale metal facing the adhesive layer, and then pattering the metal foils to create a plurality of fiducials to mark openings suitable for semiconductor chips.

26. The method of claim 24 wherein sputtering includes the sputtering of a first layer of a metal selected from a group including titanium, tungsten, tantalum, zirconium, chromium, molybdenum, and alloys thereof, the first layer adhering to chip and lamination surfaces; and without delay sputtering at least one second layer of a metal selected from a group including copper, silver, gold, and alloys thereof, onto the first layer, the second layer adhering to the first layer.

27. The method of claim 26 further comprising:
patterning and plating a layer of the third metal onto the sputtered layer of the third metal;
plating a layer of solderable metal onto selected areas of the plated third metal;
etching selected areas of the sputtered metal layers, thereby completing the assembly on both panel sides with the second terminals connected to the fiducials;
elevating the temperature to release the first adhesive and thus enable the separation of the assembled panel sides from the panel core; and
dicing the assembled panel sides to singulate discrete devices having all terminals accessible on one side.

28. The method of claim 27 further comprising, before elevating, encapsulating in lamination material for enhancing rigidity.

29. The method of claim 28 further comprising, after elevating, separating the core of clear laminate material from the assemblies by using UV-irradiation.

30. A method for fabricating packaged semiconductor devices in panel format, comprising:
providing a first panel sheet having an insulating core of clear laminate material and a surface covered by a layer of a UV-releasable first adhesive;
placing the solderable surface of a metallic grid on the adhesive surface, the grid having a plurality of openings framed by fiducials with sidewalls, each opening sized to accommodate a semiconductor chip;
attaching a plurality of semiconductor chips to the adhesive panel surfaces within the reserved spaces, the chip terminals facing the adhesive surface;
laminating, under vacuum suction, a compliant insulating material to cohesively fill gaps between chips and fiducials, the material having a coefficient of thermal expansion approaching the coefficient of the semiconductor chips, thereby creating a sheet-like assembly;
providing a second panel sheet having an insulating core and a temperature-releasable film of second adhesive covering both surfaces;
attaching the compliant insulating material of a sheet-like assembly onto each adhesive surface of the second panel, the terminals of the chips of each assembly facing away from the second panel, thereby creating a symmetrical work piece;
using UV-irradiation on the first adhesives, separating the first laminate carriers from the assemblies on both sides of the work piece, exposing the chip surface with the terminals;
plasma-cleaning both panel sides and attached chips uniformly in an equipment for sputtering metals; and
sputtering, at uniform energy and rate and while the panel is cooled, onto the chip surfaces with the terminals of both panel sides at least one layer of a metal adhering to the assembly.

31. The method of claim 30 wherein the metallic grid is created by laminating a metal foil on the layer of first adhesive, the foil having a surface with solderable metal facing the adhesive layer, and then patterning the metal foil to create a plurality of fiducials to mark openings suitable for semiconductor chips.

32. The method of claim 30, wherein the chip terminals have metal bumps.

33. The method of claim 30 wherein sputtering includes the sputtering of a first layer of a metal selected from a group including titanium, tungsten, tantalum, zirconium, chromium, molybdenum, and alloys thereof, the first layer adhering to chip and lamination surfaces; and without delay sputtering at least one second layer of a metal selected from a group including copper, silver, gold, and alloys thereof, onto the first layer, the second layer adhering to the first layer.

34. The method of claim 32 further comprising, after laminating, grinding lamination material and semiconductor chips uniformly until they form a plane with the fiducials and the panel surface is flat.

35. The method of claim 30 further comprising:
patterning and plating a layer of the third metal onto the sputtered layer of the third metal on the active chip surfaces of both panel sides;
plating a layer of solderable metal onto selected areas of the plated third metal;
etching selected areas of the sputtered metal layers, thereby completing the assembly on both panel sides;
elevating the temperature to release the second adhesives and thus enable the separation of the assembled panel sides from the second panel core; and
dicing the assembled panel sides to singulate discrete devices.

36. The method of claim 35 further comprising, before elevating, encapsulating in lamination material for enhancing rigidi37. A method for fabricating packaged semiconductor devices in panel format, comprising:
providing a panel sheet as a carrier having an insulating core with a layer of first adhesive covering each side, and first metal foils adhering to both adhesive layers, the symmetry of the panel suitable for executing certain process steps on both panel sides concurrently;
laminating second metal foils on the first foils by using layers of a second adhesive releasable at elevated temperature;
patterning the second metal foils to create a plurality of fiducials marking spaces reserved for semiconductor chips;
attaching a plurality of semiconductor chips to the second adhesive on the first metal within the reserved spaces, the chip bondpads facing the second adhesive;
laminating, under vacuum suction, a compliant insulating material to cohesively fill gaps between chips and metal patches, the material having a coefficient of thermal expansion approaching the coefficient of the semiconductor chips;
grinding lamination material and semiconductor chips uniformly until both panel surfaces are flat, thereby completing assemblies on both sides of an individual panel;
elevating the temperature to release the second adhesive and thus enable the separation of the panel core with its adhering first metal foils and second adhesives from the assemblies on both panel sides, freeing each assembly to be processed as a panel separately;
plasma-cleaning, in an equipment for sputtering metals, the second metal patches and attached chips; and
sputtering, at uniform energy and rate and while cooling the assembly, at least one layer of metal onto the assembly of lamination, second metal patches, and exposed chip bondpads, the layer adhering to the assembly.

38. The method of claim 37 wherein sputtering includes the sputtering of a first layer of a metal selected from a group including titanium, tungsten, tantalum, zirconium, chromium, molybdenum, and alloys thereof, the first layer adhering to chip and lamination surfaces; and without delay sputtering at least one second layer of a metal selected from a group including copper, silver, gold, and alloys thereof, onto the first layer, the second layer adhering to the first layer.

39. The method of claim 38 further comprising:
plating a metal layer of the sputtered metal;
patterning the plated layer to create connecting traces between chip terminals and respective fiducials anchored in the insulating material;
plating a layer of solderable metal onto selected areas of the plated metal, thereby preparing the areas as terminals of the packaged device;
depositing and patterning rigid insulating material over exposed chip portions and selected areas of the plated metal; and
dicing the individual panel to singulate discrete packaged devices.

40. The method of claim 37, wherein patterning uses a laser direct imaging technology.

41. The method of claim 40 wherein the laser direct imaging technology uses an out-alignment correcting technique.

42. A semiconductor device comprising:
a semiconductor chip having a first surface with metallized terminals, and a parallel second surface, the first surface coated with a flat layer of insulating polymer, the layer including openings to the terminals;
a frame of insulating material adhering to the sidewalls of the chip and the polymeric layer, the frame having a surface planar with the polymeric layer and a parallel surface planar with the second chip surface; and
at least one film of sputtered metal extending from the terminals across the surface of the polymeric layer to the surface of the insulating frame, the film patterned to form extended contact pads over the frame and rerouting traces between the chip terminals and the extended contact pads, the film adhering to the surfaces.

43. The device of claim 42 wherein the sputtered film includes a first layer of a metal selected from a group including titanium, tungsten, tantalum, zirconium, chromium, molybdenum, and alloys thereof, the first layer adhering to the chip terminals, polymeric surface, and frame surface; and at least one second layer of a metal selected from a group including copper, silver, gold, and alloys thereof, onto the first layer, the second layer adhering to the first layer.

44. The device of claim 43 further including at least one layer of plated metal adhering to the sputtered metals.

45. The device of claim 43 further including a device-size carrier sheet attached to the second chip surface and adjacent frame surfaces.

46. The device of claim 45 further including a patterned rigid material protecting exposed portions of the polymeric layer and rerouting traces.

47. The device of claim 46 further including a metal frame surrounding and adhering to the frame of insulating material.

48. The device of claim 42 wherein the insulating material of the frame includes glass fibers impregnated with a gluey resin having a high modulus and a coefficient of thermal expansion (CTE) close to the CTE of silicon.

49. The device of claim 42 wherein the configuration and metallurgy of the extended contact pads are selected to be suitable to devices including land grid array devices, ball grid array devices, and Quad Flat No-Lead (QFN) devices.

50. A semiconductor device comprising:
a semiconductor chip having a first surface with metallized terminals, and a parallel second surface;
a frame of insulating material adhering to the sidewalls of the chip, the frame having a first surface planar with the first chip surface and a parallel second surface planar with the second chip surface, the first frame surface including one or more embedded metallic fiducials extending from the first surface into the insulating material; and
at least one film of sputtered metal extending from the terminals across the surface of the polymeric layer to the fiducials, the film patterned to form extended contact pads over the frame and rerouting traces between the chip terminals and the extended contact pads, the film adhering to the surfaces.

51. The device of claim 50 wherein the sputtered film includes a first layer of a metal selected from a group including titanium, tungsten, tantalum, zirconium, chromium, molybdenum, and alloys thereof, the first layer adhering to the chip terminals, polymeric surface, and frame surface; and at least one second layer of a metal selected from a group including copper, silver, gold, and alloys thereof, onto the first layer, the second layer adhering to the first layer.

52. The device of claim 51 further including at least one layer of plated metal adhering to the sputtered metals.

53. The device of claim 52 further including a patterned rigid material protecting exposed portions of the polymeric layer and rerouting traces.

54. The device of claim 50 wherein the insulating material of the frame includes glass fibers impregnated with a gluey resin having a high modulus and a coefficient of thermal expansion (CTE) close to the CTE of silicon.

55. The device of claim 50 wherein the configuration and metallurgy of the extended contact pads are selected to be suitable to devices including land grid array devices, ball grid array devices, and Quad Flat No-Lead (QFN) devices.
